(19) United States
(12) Patent Application Publication
(10) Pub. No.: US 2013/0069427 A1
(43) Pub. Date: Mar. 21, 2013

(54) CIRCUIT ARRANGEMENT AND ASSOCIATED CONTROLLER FOR A MOTOR VEHICLE

(71) Applicants: Jens Nowotnick, Reutlingen (DE); Michael Heim, Holzgerlingen (DE); Stefan Keil, Kusterdingen (DE); Peter Rehbein, Thuengersheim (DE); Gerhard Braun, Rottenburg (DE); Georg Voegele, Langenargen (DE); Sigmund Braun, Kusterdingen (DE); Andreas Kulik, Gerlingen (DE)

(72) Inventors: Jens Nowotnick, Reutlingen (DE); Michael Heim, Holzgerlingen (DE); Stefan Keil, Kusterdingen (DE); Peter Rehbein, Thuengersheim (DE); Gerhard Braun, Rottenburg (DE); Georg Voegele, Langenargen (DE); Sigmund Braun, Kusterdingen (DE); Andreas Kulik, Gerlingen (DE)

(73) Assignee: ROBERT BOSCH GMBH, Stuttgart (DE)

(21) Appl. No.: 13/583,185

(22) PCT Filed: Mar. 11, 2011
(86) PCT No.: PCT/EP2011/053730

§ 371 Date: Dec. 6, 2012

(30) Foreign Application Priority Data
Mar. 17, 2010 (DE) 102010002950.5

(51) Int. Cl. H05K 7/14; H05K 5/02; H05K 7/20; B60L 1/00

(52) U.S. Cl. 307/10.1; 361/679.01; 361/813; 361/720

(57) ABSTRACT

The invention relates to a circuit arrangement (1) comprising an electrical and/or electronic circuit unit (10), which comprises a circuit carrier (14), on which at least one electrical and/or electronic component (12) is arranged, and at least one connection region (5) with at least one contact unit (14.2) for electrically contact-connecting the electrical and/or electronic circuit unit (10) to other electrical and/or electronic structural units, wherein at least one region of the circuit unit (10) is arranged in a housing unit (20) sealed relative to the surroundings. According to the invention, the housing unit (20) comprises a protective compound which surrounds the at least one region of the circuit unit (10) in a sealing fashion and surrounds the at least one connection region (5) in such a way that the at least one contact unit (14.2) is embedded at least at its side areas into the protective compound (22).

### BACKGROUND OF THE INVENTION

The invention is based on a circuit arrangement and on a controller for a motor vehicle having such a circuit arrangement.

Controllers are generally known for controlling the most varied functions and devices and are increasingly used in the automotive field for controlling the most varied functions of a motor vehicle. These controllers are available in the most varied mechanical designs. A controller usually comprises at least one circuit arrangement comprising an electrical and/or electronic circuit unit which comprises a circuit carrier on which at least one electrical and/or electronic component is arranged, and at least one connection region with at least one contact unit for electrically contact-connecting the electrical and/or electronic circuit unit to other electrical and/or electronic structural units such as, for example, actuators, sensors or plugs. As a rule, the circuit unit is arranged within a housing unit sealed against the environment.

In published patent application DE 10 2005 015 717 A1, for example, an electrical circuit arrangement, especially for a motor vehicle, and an associated controller are described. The electrical circuit arrangement described comprises a circuit carrier with electrical circuit elements and a connecting device used for electrically linking the circuit carrier. The circuit arrangement is arranged in a housing sealed against an environment, which housing has a bottom element and a lid element. The lid element is sealed with respect to the bottom element via a peripheral sealing element. In addition, electrical components are arranged on an area of the connection arrangement lying within the housing. The circuit carrier described is constructed, for example, as ceramic circuit carrier, especially as LTCC (low temperature cofire ceramic) circuit carrier and the connecting unit described is constructed, for example, as circuit board, flexible circuit board, flexible foil or as lead frame.

In patent specification U.S. Pat. No. 7,514,784 B2, an electronic circuit unit and a corresponding production method are described. The circuit unit described comprises a circuit carrier on which electronic components, conductor tracts and metal terminals for electrically contact-connecting the circuit carrier are arranged. In this context, the electronic components and the conductor tracks are surrounded by a protective compound and the metal terminals for electrical contact-connection are arranged outside the protective compound. The metal terminals for contact-connecting are arranged on both sides of the circuit carrier, wherein the individual metal terminals can only be contact-connected on one surface.

### SUMMARY OF THE INVENTION

The circuit arrangement according to the invention, in comparison, has the advantage that the housing unit comprises a protective compound which surrounds at least one area of the circuit unit in a sealing manner and surrounds the at least one connection area in such a manner that the at least one contact unit is embedded into the protective compound at least at its side faces. The electrical and/or electronic circuit unit comprises, for example, a circuit carrier on which at least one electrical and/or electronic component is arranged, and at least one connection area having at least one contact unit for electrically contact-connecting the electrical and/or electronic circuit unit to other electrical and/or electronic structural units.

The circuit arrangement according to the invention can be used, for example, in a controller for a motor vehicle, which is used, for example, as performance module for controlling electrical drives of all performance classes such as, e.g. steering drives, hybrid vehicle drives, electric vehicle drives, small motors such as wipers, window lifters, cooling water pumps etc. In addition, uses are conceivable wherever electronic assemblies must be protected for further processing.

In a so-called molding process, the open electrical and/or electronic circuit unit obtains a stable housing shape by means of the protective compound or casting compound. Embodiments of the present invention, as a result, fulfill two essential points, on the one hand the protection of the circuit carrier and its components against external influences such as, for example, temperature, dirt and/or water and, on the other hand, the possibility of direct contact-connection of the circuit carrier to other electrical structural units such as, for example, a cable tree. By surrounding the equipped circuit carrier, preferably carried out by surrounding-molding, with the protective compound, several of the normally used production steps can be omitted, as a result of which costs can be advantageously saved. During the surrounding-molding, the equipped circuit carrier is sheathed or cast directly with a protective compound made as plastic, preferably with a duroplastic, as a result of which the normally used housing components such as housing base and housing top can be omitted. Associated with this, some assembly steps are dispensed with in production such as, for example, supplying the housing components, screwing the circuit carrier to the housing bottom, applying a seal acting between housing bottom and housing top, placing the housing top onto the housing bottom, screwing the two housing components together are dispensed with in production. In particular, the at least lateral embedding of the contact units into the protective compound or casting compound or molding compound results in a stable connection area which provides for direct contact-connection of the circuit carrier to other electrical and/or electronic structural units which have a corresponding counterplug. Thus, the circuit carrier can be connected electrically via the connection area and the associated counterplug, for example, directly to a cable tree. In this context, the detachability of the connection between the circuit carrier and the associated counterplug or the omission of using separate contact-connection methods such as, for example, producing welding, soldering or cutting clamped connections etc. is advantageous. In addition, contact connection units such as, for example, a male multipoint connector used additionally can be omitted. As a result, the production costs for a circuit arrangement can be advantageously lowered and a compact, comparatively small circuit arrangement protected well against environmental influences is produced which can be used in a motor vehicle controller.

It is particularly advantageous that the circuit carrier is constructed as at least one lead frame assembly having individual arranged conductor tracks, wherein the at least one contact unit is constructed as contact blade of the circuit carrier constructed as lead frame assembly in order to provide for direct contact-connection to other electrical and/or electronic structural units. For this purpose, the corresponding contact units constructed as contact blades are designed, for example, in such a manner that they are arranged in one plane or line and the existing intermediate spaces are filled with molding compound during the molding process.

In an advantageous embodiment of the circuit arrangement according to the invention, the arranged conductor tracks of the circuit carrier constructed as lead frame assembly are arranged in at least two different planes. The conductor tracks arranged in at least two different planes are configured, for example, in such a manner that partial multi-layered arrangements form a conductor track cross-over and/or a capacitance. As a result, conductor track cross-overs of the circuit unit, required in the layout, which are predetermined by the corresponding circuit, can be implemented without using additional components such as wire bonds, bridges etc. By means of the capacitances formed, discrete capacitor components required for interference suppression or circuit related reasons can be advantageously replaced. As a result, the standard contact-connection of the discrete capacitor components by means of soldered assembly is also advantageously no longer required. Conductor track cross-overs and/or capacitors are thus represented by three-dimensional molding of the lead frame assembly in distinction from the state of the art to date. For example, the lead frame assembly can be held by a moldable adhesive foil. The partial multi-layered arrangement of the lead frame assembly or circuit carrier material produced in this manner can also be constructed or used additionally as (plate) capacitor by suitable specification of the geometry, which (plate) capacitor, for example, can be used for electrical interference suppression and/or stabilization of a link circuit voltage. Due to the multi-layered arrangement of the individual conductor tracks, it is possible in the simplest manner to arrange also the contact blades of the contact unit in more than one plane. As an alternative, contact blades of one plane of conductor tracks can also be brought into different planes with respect to one another by bending the lead frame. Similarly, the contact blades provided in a common plane can be arranged offset laterally with respect to one another, for example offset alternatingly. Such embodiments of the contact blades enable a contact-connection unit for forming a multi-layered plug-in connection to be constructed.

In a further advantageous embodiment of the circuit arrangement according to the invention, the shape and/or size of the at least one contact unit are matched to the mechanical and/or electrical requirements such as, for example, to the current-carrying capacity. In another advantageous embodiment, the at least one contact unit is constructed to be simultaneously contact-connectable on the top and/or bottom. As a result, applications with high currents are advantageously favored.

In a further advantageous embodiment of the circuit arrangement according to the invention, the circuit carrier is arranged at least partially on a thermally conductive baseplate which is surrounded at least partially by the protective compound. The thermally conductive baseplate is constructed, for example, as metal plate having an applied insulating layer. For forming a ground connection, the insulating layer can have a recess. The insulating layer can be applied, completely or partially to the thermally conductive baseplate, for example, by painting, bonding-on of a foil, printing, an exposure process, anodizing etc. Suitable as thermal baseplates are, in particular, extruded sections—for example of aluminum. Extruded sections allow a longitudinally oriented construction of a cross-sectional contour, which allows a simple and matched assembly of the circuit arrangement via the extruded section on an adjacent component or assembly, for example a cylindrical housing of a drive motor.

By integrating the thermally conductive baseplate into the circuit arrangement, an optimal thermal linkage of the circuit carrier or of the lead frame assembly, respectively, and a stable assembly with the housing unit comprising protective compound can be achieved. In this context, the insulating layer is applied as thinly as possible and can be designed at the same time as adhesive layer for attaching the circuit carrier or the lead frame assembly, respectively. The baseplate takes over the function of a heat sink. In addition, the integrated thermally conductive baseplate enables the heat path to be continued simply to a further heat sink. Thus, the baseplate can be connected to the further heat sink, for example, by welding, pressing, beading, bonding, riveting etc. The circuit arrangement with integrated baseplate can be used, for example, in applications in a motor vehicle which require advantageous heat dissipation characteristics. Thus, the circuit arrangement can be used, for example, in highly integrated controller assemblies for xenon controllers.

Exemplary embodiments of the invention are shown in the drawings and will be explained in greater detail in the description following.

### BRIEF DESCRIPTION OF THE DRAWINGS

FIG. 1 shows a diagrammatic perspective view of a first exemplary embodiment of a circuit arrangement according to the invention.

FIG. 2 shows a diagrammatic top view of the first exemplary embodiment of the circuit arrangement according to the invention from FIG. 1, the protective compound being represented as being transparent for better orientation.

FIG. 3 shows a sectional view of the first exemplary embodiment of the circuit arrangement according to the invention along section line III-III in FIG. 2, and of a mating connector for contact-connection of the circuit arrangement according to the invention.

FIG. 4 shows a sectional view of the first exemplary embodiment of the circuit arrangement according to the invention along section line IV-IV in FIG. 2.

FIG. 5 shows a diagrammatic perspective view of a thermally conductive baseplate for a circuit arrangement according to the invention.

FIG. 6 shows a diagrammatic perspective view of the thermally conductive baseplate from FIG. 5 with applied circuit carrier, connection area and electrical and/or electronic components.

FIG. 7 shows a diagrammatic perspective view of a second exemplary embodiment of a circuit arrangement according to the invention comprising the thermally conductive baseplate from FIG. 5.

FIG. 8 shows a diagrammatic perspective view of a section of a circuit carrier constructed as lead frame assembly for the circuit arrangement according to the invention from FIG. 1 or 7.

### DETAILED DESCRIPTION

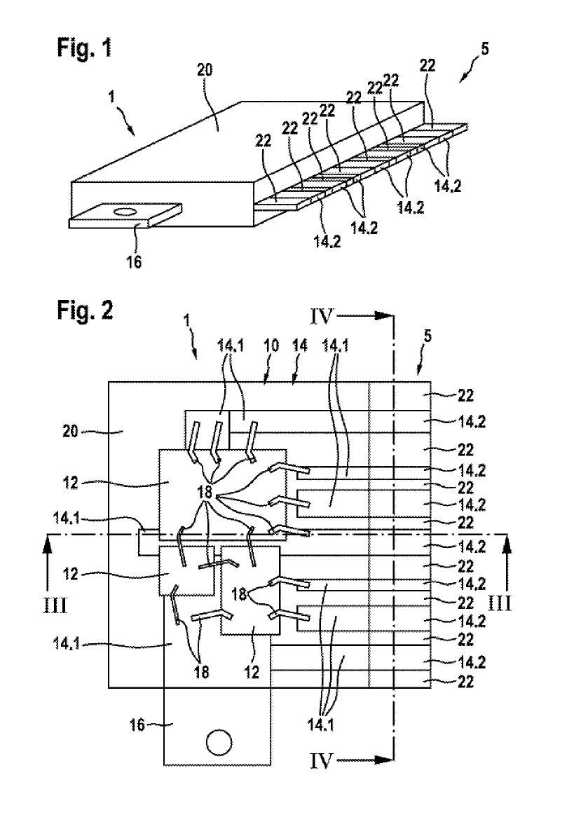

As can be seen from FIGS. 1 to 4, a first exemplary embodiment of a circuit arrangement 1 according to the invention comprises an electrical and/or electronic circuit unit 10 which comprises a circuit carrier 14 on which several electrical and/or electronic components 12 are arranged, and a connection area 5 comprising several contact units 14.2 for electrically contact-connecting the electrical and/or electronic circuit unit 10 to other electrical and/or electronic structural units 30. The circuit unit 10 is arranged in a housing unit 20 sealed against the environment. According to the invention, the housing unit 20 comprises a protective compound which surrounds the circuit unit 10 in a sealing manner and surrounds the connection area 5 in such a manner that the contact units 14.2 are embedded in the protective compound 22 at least at their side faces.

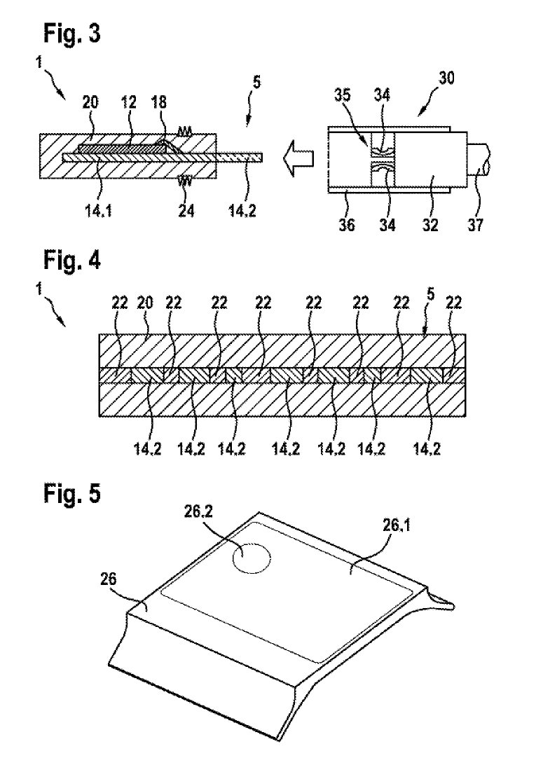

As can further be seen from FIGS. 1 to 4, the circuit carrier 14 is constructed as lead frame assembly with individual conductor tracks 14.1 arranged within the protective compound 20. In this arrangement, the contact units 14.2 arranged outside the protective compound 20 are constructed as contact blades, lying in one plane, of the circuit carrier 14 constructed as lead frame assembly in order to provide for direct contact-connection to the other electrical and/or electronic components 30. The existing spaces 22 between the contact units 14.2 constructed as contact blades are also filled with molding compound during the molding process and impart to the connection area 5 the required stability and strength for implementing the direct contact-connection. As can also be seen from FIG. 2 or 3, the electrical and/or electronic components 12 can be electrically connected via connecting elements 18 which, for example, are constructed as bonding wires, to one another and/or to the conductor tracks 14.1 of the circuit carrier 14 constructed as lead frame assembly. As can also be seen from FIG. 1 or 2, two electrical and/or electronic components 12 are arranged on a conductor track 14.1 which protrudes out of the protective compound 20 as cooling element 16 or cooling tab. The cooling element 16 can be connected to a heat sink, not shown, and/or to a ground contact, not shown, for dissipating waste heat.

As can also be seen from FIG. 3, a corresponding contact-connecting device 30 constructed as mating connector has a connection area 35 and a contact carrier 32 with protruding elastic contact elements 34 for contact-connecting the circuit arrangement 1 to a cable tree 37, the connection area 35 and the contact carrier 32 being arranged within a housing 36. For the contact-connection, the circuit arrangement 1 is inserted with the connection area 5 into the connection area 35 of the contact-connecting device 30 until the elastic contact elements 34 rest on the surfaces of the contact units 14.2. In the exemplary embodiment shown, the contact units 14.2 are in each case contact-connected on the top and bottom. Shape and/or size of the contact units 14.2 are adapted to the mechanical and/or electrical arrangements. Thus, for example, the width and the thickness of the contact units 14.2 can be designed to be different. Similarly, the contact units 14.2 can be arranged at different distances from one another. A peripheral radial seal 24 seals the protective compound 20 against corresponding inner faces of the housing 36 of the contact-connecting device 30 in order to protect the electrical contact-connecting against environmental influences and/or media.

As can be seen from FIGS. 5 to 7, a second exemplary embodiment of a circuit arrangement 1′ according to the invention comprises an electrical and/or electronic circuit unit 10′ and a thermally conductive baseplate 26, constructed as a metal plate, with an applied insulating layer 26.1. The insulating layer 26.1 has a recess 25.2 for forming a ground connection. Analogously to the first exemplary embodiment, the electrical and/or electronic circuit unit 10′ comprises a circuit carrier 14′ on which several electrical and/or electronic components 12 are arranged, and a connection area 5′ comprising a number of contact units 14.2′ for the electrical contact-connection of the electrical and/or electronic circuit unit 10′ to other electrical and/or electronic components 30.

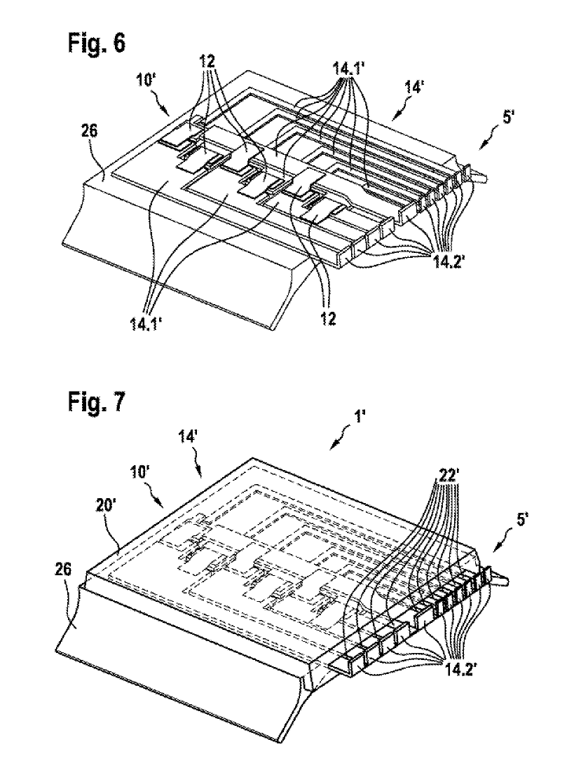

As can be seen from FIG. 6 or 7, the circuit carrier 14′, analogously to the first exemplary embodiment, is constructed as lead frame assembly having individual conductor tracks 14.1′ arranged within the protective compound 20′, on which conductor tracks several electrical and/or electronic components 12 are arranged. The conductor tracks 14.1′ are connected to the thermally conductive baseplate 26 via the insulating layer 26.1, wherein the insulating layer 26.1 itself can be designed as adhesive. Analogously to the first exemplary embodiment, the contact units 14.2′ arranged outside the protective compound 20′ are also designed as contact blades, lying in one plane, of the circuit carrier 14′ constructed as lead frame assembly, in order to provide for a direct contact-connection to the other electrical and/or electronic components 30. The existing spaces 22′ between the contact units 14.2′ constructed as contact blades are also filled with molding compound during the molding process and impart to the connection area 5′ the necessary stability and strength for implementing the direct contact-connection.

As can also be seen from FIG. 7, the thermally conductive baseplate 26 is not completely surrounded by the protective compound 20′. As a result, the integrated thermally conductive baseplate 26 permits a simple continuation of the heat path to a heat sink, not shown. Thus, the baseplate 26 can be connected to the heat sink, for example, by welding, pressing, beading, bonding, riveting, etc. In addition, various large electrical and/or electronic components or plugs, which are not to be surrounded by the protective compound 20′, can be arranged on an area of the thermally conductive baseplate 26 which is not surrounded by the protective compound 20′ in an exemplary embodiment, not shown.

Due to the integration of the metallic baseplate 26 into the circuit arrangement 1′, an optimal thermal linking of the electrical and/or electronic components 12 can be effected via the lead frame assembly 14′. In addition, a stable assembly of circuit unit 10′ and baseplate 26 is produced.

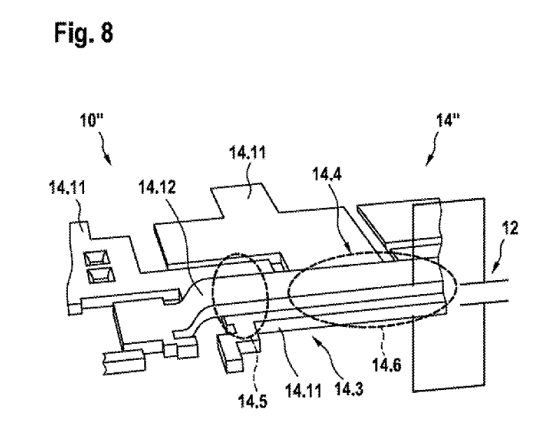

As can be seen from FIG. 8, the arranged conductor tracks 14.11, 14.12 of the circuit carrier 14″ constructed as lead frame can be arranged in at least two different planes 14.3, 14.4. The conductor tracks 14.11, 14.12 arranged in at least two different planes 14.3, 14.4 can be configured, for example, in such a manner that partial multi-layered arrangements form a conductor track cross-over 14.5 and/or a capacitance 14.6. As a result, conductor track cross-overs 14.5, necessary due to specifications of the corresponding circuit in the layout, of the circuit unit 10, 10′ can be implemented without using additional components such as wire bonds, bridges etc. Due to the capacitances formed, discrete capacitor components 12 required for interference suppression or circuit related reasons can be advantageously replaced. In distinction from the previous state of the art, conductor track cross-overs and/or capacitors are represented by three-dimensional forming of the lead frame assembly 14″.

The circuit arrangement according to the invention can be used, for example, in a controller for a motor vehicle which is used, for example, as performance module for controlling electrical drives of all performance classes such as, e.g., steering drives, hybrid vehicle drives, electric vehicle drives, small motors such as wipers, window lifters, cooling water pumps, etc. In addition, uses are conceivable wherever electronic components must be protected for further processing.

1. A circuit arrangement comprising an electrical and/or electronic circuit unit (10, 10′, 10″) which comprises a circuit carrier (14, 14′), on which at least one electrical and/or electronic component (12) is arranged, and at least one connection area (5, 5′) with at least one contact unit (14.2. 14.2′) for electrically contact-connecting the electrical and/or electronic circuit unit (10, 10′, 10″) to other electrical and/or electronic structural units (30), wherein at least one area of the circuit unit (10, 10′, 10″) is arranged in a housing unit (20, 20′) sealed against the environment, characterized in that the housing unit (20, 20′) comprises a protective compound which surrounds the at least one area of the circuit unit (10, 10′) in a sealing manner and surrounds the at least one connection area (5, 5′) in such a manner that the at least one contact unit (14.2, 14.2′) is embedded into the protective compound (22, 22′) at least at its side faces.

2. The circuit arrangement as claimed in claim 1, characterized in that the circuit carrier (14, 14′) is constructed as at least one lead frame assembly having individual arranged conductor tracks (14.1, 14.1′, 14.11, 14.12), wherein the at least one contact unit (14.2, 14.2′) is constructed as contact blade of the circuit carrier (14, 14′) constructed as lead frame assembly in order to provide for direct contact-connection to other electrical and/or electronic structural units (30).

3. The circuit arrangement as claimed in claim 2, characterized in that the arranged conductor tracks (14.1, 14.1′, 14.11, 14.12) of the circuit carrier (14, 14′) constructed as lead frame assembly are arranged in at least two different planes (14.3, 14.4).

4. The circuit arrangement as claimed in claim 3, characterized in that the conductor tracks (14.1, 14.1′, 14.11, 14.12) arranged in at least two different planes (14.3, 14.4) are configured in such a manner that partial multi-layered arrangements form a conductor track cross-over (14.5) and a capacitance (14.6).

5. The circuit arrangement as claimed in claim 1, characterized in that the shape and/or size of the at least one contact unit (14.2, 14.2′) are matched to the mechanical and electrical requirements.

6. The circuit arrangement as claimed in claim 1, characterized in that the at least one contact unit (14.2, 14.2′) is contact-connectable on the top and bottom.

7. The circuit arrangement as claimed in claim 1, characterized in that the circuit carrier (14, 14′) is arranged at least partially on a thermally conductive baseplate (26) which is surrounded at least partially by the protective compound (20′).

8. The circuit arrangement as claimed in claim 7, characterized in that the thermally conductive baseplate (26) is constructed as a metal plate having an applied insulating layer (26.1).

9. The circuit arrangement as claimed in claim 8, characterized in that the insulating layer (26.1) has a recess (25.2) for forming a ground connection.

10. A controller for a motor vehicle characterized by a circuit arrangement as claimed claim 1.

11. The circuit arrangement as claimed in claim 3, characterized in that the conductor tracks (14.1, 14.1′, 14.11, 14.12) arranged in at least two different planes (14.3, 14.4) are configured in such a manner that partial multi-layered arrangements form a conductor track cross-over (14.5).

12. The circuit arrangement as claimed in claim 3, characterized in that the conductor tracks (14.1, 14.1′, 14.11, 14.12) arranged in at least two different planes (14.3, 14.4) are configured in such a manner that partial multi-layered arrangements form a capacitance (14.6).

13. The circuit arrangement as claimed in claim 1, characterized in that the shape and/or size of the at least one contact unit (14.2, 14.2′) are matched to the mechanical requirements.

14. The circuit arrangement as claimed in claim 1, characterized in that the shape and/or size of the at least one contact unit (14.2, 14.2′) are matched to the electrical requirements.

15. The circuit arrangement as claimed in claim 1, characterized in that the at least one contact unit (14.2, 14.2′) is contact-connectable on the top.

16. The circuit arrangement as claimed in claim 1, characterized in that the at least one contact unit (14.2, 14.2′) is contact-connectable on the bottom.
